(19) United States
(12) Patent Application Publication
(10) Pub. No.: US 2014/0060427 A1
(43) Pub. Date: Mar. 6, 2014

(54) CRYSTAL GROWING DEVICE

(71) Applicants: Jen-Pin YU, New Taipei City (TW); Chen-Wei CHANG, New Taipei City (TW); Chia-Ying HSIEH, New Taipei City (TW)

(72) Inventors: Jen-Pin YU, New Taipei City (TW); Chen-Wei CHANG, New Taipei City (TW); Chia-Ying HSIEH, New Taipei City (TW)

(73) Assignee: C Sun Mfg. Ltd., New Taipei City (TW)

(21) Appl. No.: 13/753,502

(22) Filed: Jan. 29, 2013

(30) Foreign Application Priority Data
Sep. 4, 2012 (TW) 101217002

(51) Int. Cl. C30B 11/00

(52) U.S. Cl. CPC C30B 11/003
USPC 118/400

(57) ABSTRACT

A crystal growing device includes a furnace, a platform, a crucible, a heating unit, a heat transmitting block, and a heat exchanger. The furnace defines a chamber therein. The platform is disposed in the chamber and has a top surface and a bottom surface. The crucible is disposed on the top surface of the platform for receiving a crystal seed layer and a raw material therein. The heating unit is disposed in the chamber and surrounds the crucible. The heat transmitting block is disposed at the bottom surface of the platform and is made of a material with high thermal conductivity. The heat exchanger is coupled to the heat transmitting block for absorbing heat from the heat transmitting block.

### CROSS-REFERENCE TO RELATED APPLICATION

This application claims priority of Taiwanese Application No. 101217002, filed on Sep. 4, 2012.

### BACKGROUND OF THE INVENTION

1. Field of the Invention

This invention relates to a crystal growing device, more particularly to a crystal growing device including a heat exchanger.

2. Description of the Related Art

Referring to FIG. 1, a conventional crystal growing device 900 is shown to include a platform 95, a crucible 92 disposed on the platform 95 for receiving a crystal seed layer 94 and a silicon material 93, and a plurality of heaters 91 disposed around the crucible 92. A crystal growing process may include the following stages: heating, melting, crystallizing, annealing, and cooling. When the crystal growing device 900 is utilized, the silicon material 93 is heated by the heaters 91 at the heating stage and melted completely at the melting stage. At the crystallizing stage, the molten raw material 93 starts to crystallize and solidify upwardly from the crystal seed layer 94, which is provided therebelow, thus forming a crystal 98 (see FIG. 2) after the crystallizing stage. The crystal growing device 900 further includes a heat exchanger 96 disposed at a bottom surface of the crucible 92 along an axis (A) of the crucible 92 and penetrating through the platform 95. The heat exchanger 96 is adopted for absorbing heat from the crucible 92 to prevent the crystal seed layer 94 from melting at the melting stage and is capable of controlling a temperature of the raw material 93 at the different stages of the crystal growing process.

However, since the heat exchanger 96 only has direct contact with the bottom surface of the crucible 92 close to the axis (A), the heat exchanger 96 is only capable of cooling a portion of the crystal seed layer 94 proximate to the axis (A) instead of the whole crystal seed layer 94 at the melting stage. Other portions of the crystal seed layer 94 which are away from the heat exchanger 94 may be melted, resulting in an undesired shape of the crystal 98 (see FIG. 2). Besides, during the crystallizing stage, a portion of the silicon material 93 close to the axis (A) has lower temperature, resulting in a faster crystallization thereof compared to other portions of the silicon material 93, such that an uneven surface is formed on top of the crystal 98 when the process is finished (as shown in FIG. 2). Such uneven surface of the crystal 98 is undesired and leads to waste of the crystal 98. Also, it is essential to know the temperature of the silicon material 93 proximate to the axis (A) in order to control the crystal growing process during the different stages. Nevertheless, since the heat exchanger 96 occupied a space close to the axis (A) under the crucible 94, a temperature sensor 97 is thus disposed away from the axis (A). The temperature of the silicon material 93 proximate to the axis (A) may not be measured, and the crystal growing process may not be controlled accurately to obtain the crystal 98 with a desired shape.

### SUMMARY OF THE INVENTION

Therefore, the object of the present invention is to provide a crystal growing device that is capable of growing a crystal with an even top surface to achieve a higher utilization ratio of the crystal and a higher yield of a crystal growing process.

According to the present invention, a crystal growing device includes a furnace, a platform, a crucible, a heating unit, a heat transmitting block, and a heat exchanger. The furnace defines a chamber therein. The platform is disposed in the chamber and has a top surface and a bottom surface. The crucible is disposed on the top surface of the platform for receiving a crystal seed layer and a raw material therein. The heating unit is disposed in the chamber and surrounds the crucible. The heat transmitting block is disposed at the bottom surface of the platform and is made of a material with high thermal conductivity. The heat exchanger is coupled to the heat transmitting block for absorbing heat from the heat transmitting block.

Preferably, the heat transmitting block has a top surface in direct contact with the bottom surface of the platform.

Preferably, the heat transmitting block further has a bottom surface, an upper side surface connected to the top surface of the heat transmitting block, and a lower side surface connected to the upper side surface and the bottom surface of the heat transmitting block and tapering downwardly from the upper side surface.

Preferably, an angle formed between the lower side surface and the bottom surface of the heat transmitting block ranges from 145° to 165°.

Preferably, a surface area of the top surface of the heat transmitting block is not less than 70% of a surface area of the bottom surface of the platform.

Preferably, the material from which the heat transmitting block is made is selected from graphite, molybdenum, and tungsten.

Preferably, the heat exchanger includes a fluid supplying unit for supplying a fluid, a flow controlling unit connected to the fluid supplying unit for controlling a flow rate of the fluid, and a heat exchanging unit connected to the flow controlling unit and in contact with the heat transmitting block.

Preferably, the platform defines a first channel therein, the heat transmitting block defines a second channel therein that is in spatial communication with the first channel, and the heat exchanging unit defines a third channel therein that is in spatial communication with the second channel. The first channel, the second channel, and the third channel extend along an axis of the crucible. The crucible has a bottom surface. The crystal growing device further includes a temperature sensor that is disposed in the first channel, the second channel and the third channel, and that has one end proximate to the bottom surface of the crucible.

Preferably, the heat exchanging unit includes an outer tubular body in contact with the heat transmitting block, and an inner tubular body disposed in the outer tubular body and establishing fluid communication between the flow controlling unit and the outer tubular body. The outer tubular body defines the third channel therein.

Preferably, the heat transmitting block has a thickness, and the outer tubular body is partially inserted into the heat transmitting block from the bottom surface of the heat transmitting block to an insertion depth that ranges from 25% to 45% of the thickness of the heat transmitting block.

Preferably, the fluid supplied by the fluid supplying unit has high thermal conductivity. More preferably, the fluid supplied by the fluid supplying unit is an inert gas.

The effect of the present invention resides in that the heat transmitting block absorbs heat evenly from the platform, and the heat exchanger takes away heat from the heat transmitting block, so as to keep the temperature of any part of the crystal seed layer lower than the melting point during the melting stage. As a result, a crystal which is grown evenly and upwardly with a smoother top surface may be obtained.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a sectional view of a conventional crystal growing device;

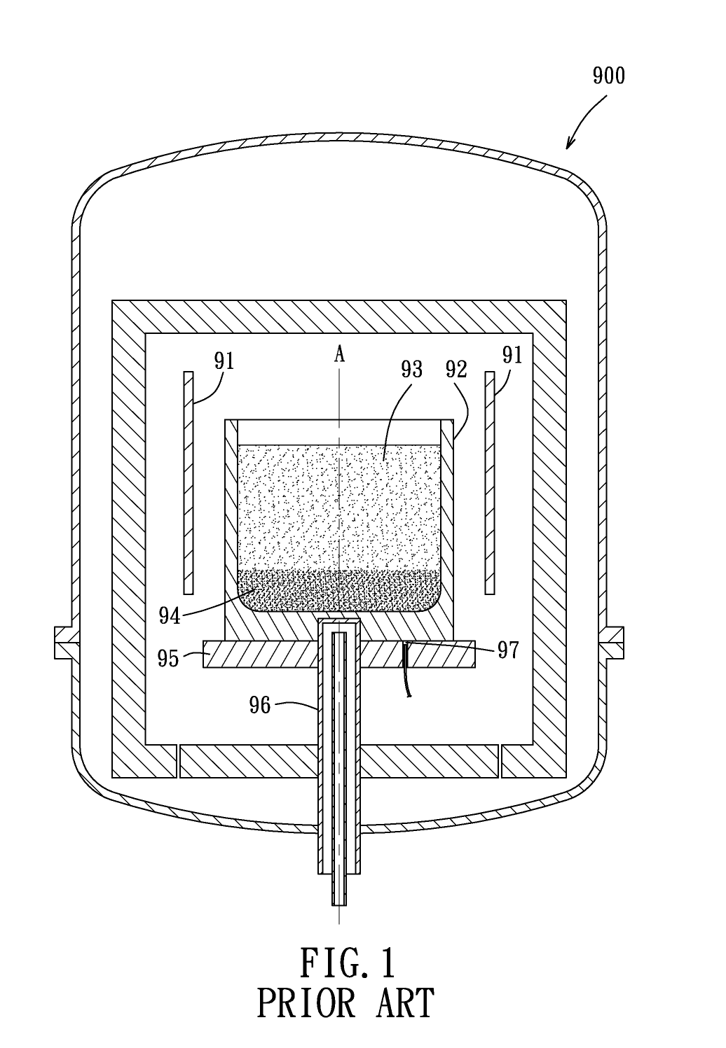

FIG. 2 is a sectional view showing a crucible of the conventional crystal growing device and a crystal grown in the crucible;

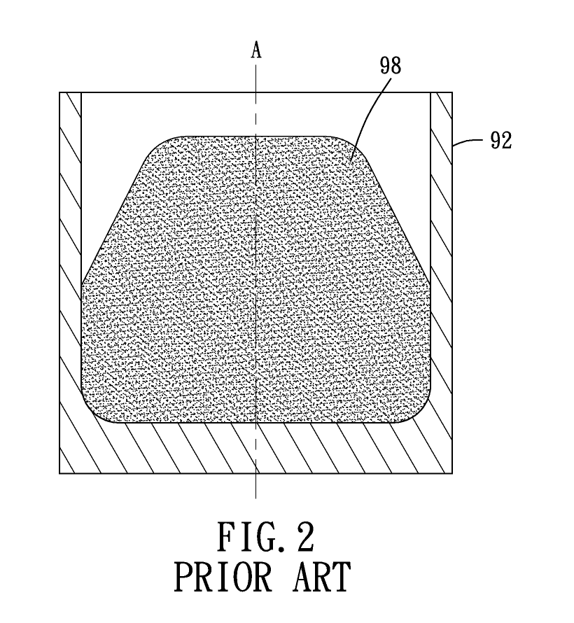

FIG. 3 is a sectional view of a crystal growing device of a preferred embodiment of the present invention;

FIG. 4 is a sectional view of a portion of the crystal growing device of the preferred embodiment; and

FIG. 5 is a sectional view showing a crucible of the crystal growing device of the preferred embodiment and a crystal grown in the crucible.

### DETAILED DESCRIPTION OF THE PREFERRED EMBODIMENT

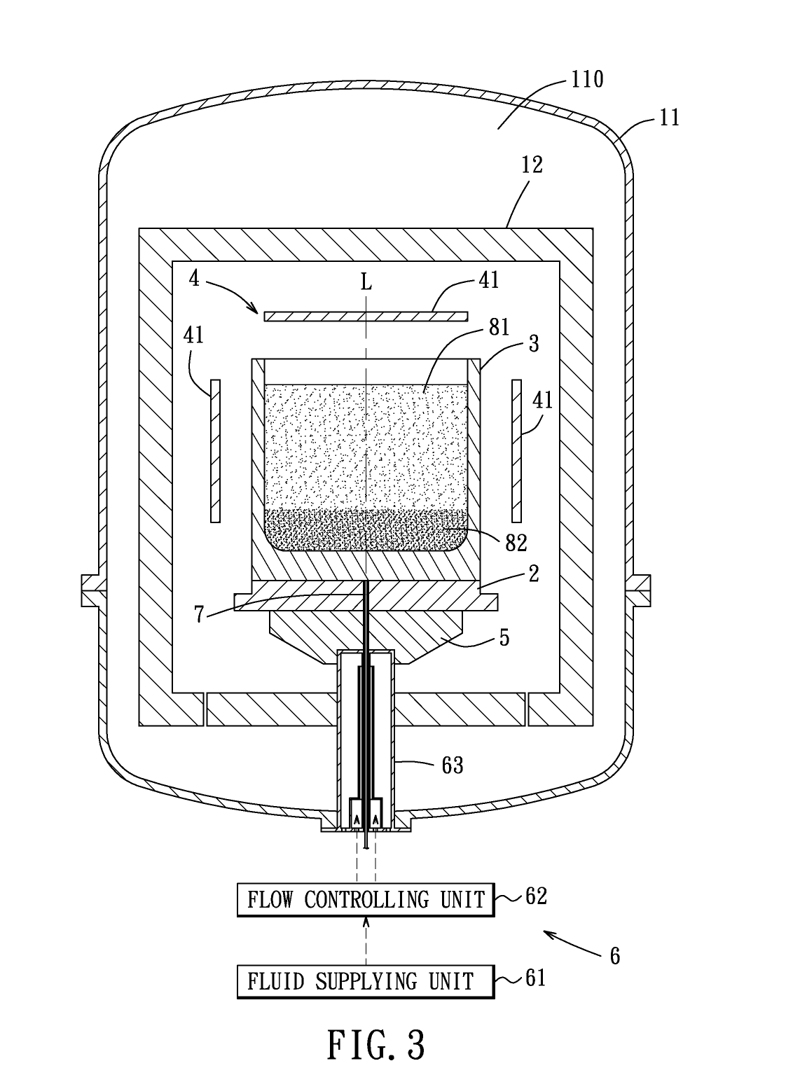

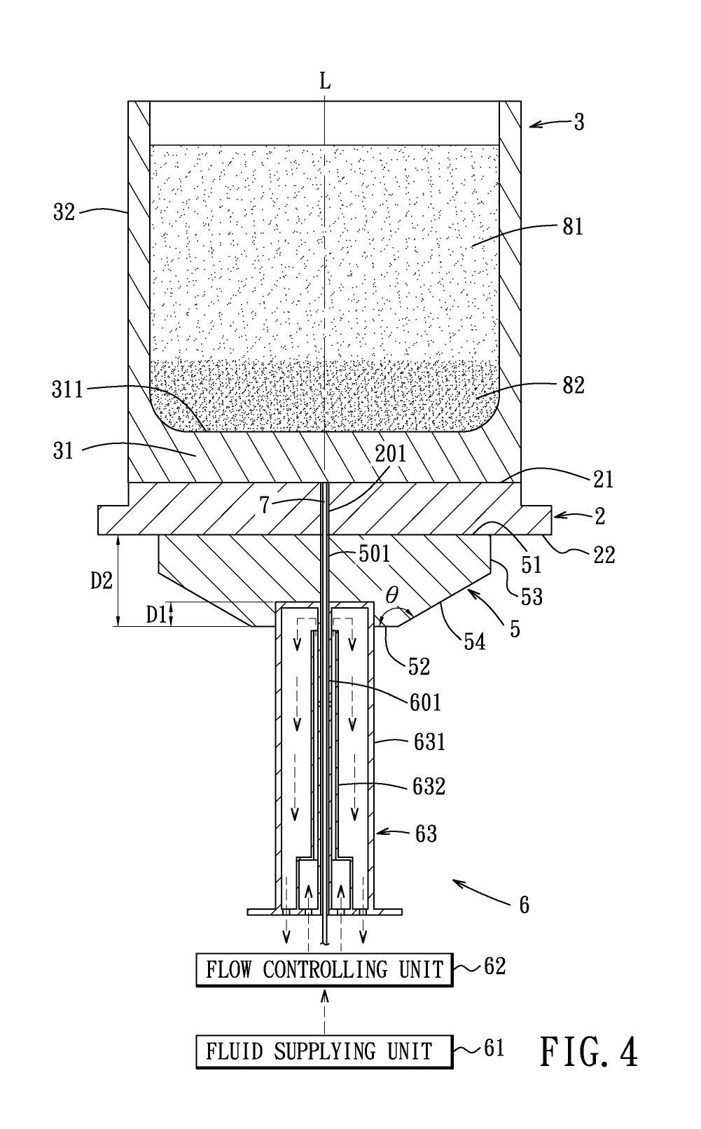

As shown in FIGS. 3 and 4, a crystal growing device of a preferred embodiment according to the present invention is provided for a crystal growing process. The crystal growing device includes a furnace 11, a cage 12, a platform 2, a crucible 3 with an axis (L), a heating unit 4, a heat transmitting block 5, a heat exchanger 6, and a temperature sensor 7.

The furnace 11 defines a chamber 110 therein. The platform 2 is disposed in the chamber 110 and has a top surface 21 and a bottom surface 22. The platform 2 is made of a material with high thermal conductivity in this preferred embodiment and defines a first channel 201 therein along the axis (L).

The crucible 3 is disposed in the chamber 110 and on the top surface 21 of the platform 2 for receiving a crystal seed layer 82 and a raw material 81 therein. The crucible 3 has a bottom wall 31 and a surrounding wall 32 extending upwardly from a periphery of the bottom wall 31. The crystal seed layer 82 is disposed on an inner surface 311 of the bottom wall 31. The raw material 81 is provided on the crystal seed layer 82 and is, but not limited to, a silicon material in this preferred embodiment. Since the bottom wall 31 of the crucible 3 has direct contact with the platform 2, heat of the crucible 3 is capable of being transmitted to the platform 2.

The heating unit 4 is disposed in the chamber 110 and includes a plurality of heaters 41 surrounding the crucible 3 for heating up the raw material 81 during the crystal growing process. The cage 12 is disposed in the chamber 110 and surrounds the crucible 3. The cage 12 is capable of moving upwardly or downwardly relative to the crucible 3. During a crystallizing stage of the crystal growing process, the cage 12 will move slowly and upwardly so as to cool the molten raw material 82 from the bottom and crystallizing the raw material 82 from the crystal seed layer 82 to solidify upwardly.

The heat transmitting block 5 is disposed at the bottom surface 22 of the platform 2 and has a top surface 51, a bottom surface 52, an upper side surface 53 connected to the top surface 51, and a lower side surface 54 connected to the upper side surface 53 and the bottom surface 54. The lower side surface 54 is tapered downwardly from the upper side surface 53 to the bottom surface 52. The heat transmitting block 5 defines a second channel 501 therein along the axis (L) and in spatial communication with the first channel 201 of the platform 2. The top surface 51 of the heat transmitting block 5 abuts against the bottom surface 22 of the platform 2 for absorbing heat therefrom. Since the heat transmitting block 5 is made of a material with high thermal conductivity, heat absorbed from the platform 2 will be distributed quickly and evenly from the top surface 51 throughout the whole heat transmitting block 5. The heat transmitting block 5 in this preferred embodiment is made of graphite, and it may be made of molybdenum or tungsten in other embodiments. Also, a larger surface area of the top surface 51 of the heat transmitting block 5 leads to a faster heat transmission so as to obtain a more even heat distribution of the platform 2. Preferably, the surface area of the top surface 51 of the heat transmitting block 5 is not less than 70% of a surface area of the bottom surface 22 of the platform 2. Additionally, a shape of the heat transmitting block 5 will affect the heat distribution therein. An angle θ formed between the lower side surface 54 and the bottom surface 52 of the heat transmitting block 5 and ranging from 145° to 165° is preferred in order to have a more uniform heat distribution of the heat transmitting block 5.

The heat exchanger 6 includes a fluid supplying unit 61 to supply a fluid, a flow controlling unit 62 in fluid communication with the fluid supplying unit 61 for controlling a flow rate of the fluid, and a heat exchanging unit 63 in fluid communication with the flow controlling unit 62 and in direct contact with the heat transmitting block 5. The fluid supplied by the fluid supplying unit 61 has high thermal conductivity, and preferably, the fluid is an inert gas or a liquid such as water. More preferably, the fluid is argon or helium. The flow controlling unit 62 is capable of controlling the flow rate of the fluid so as to adjust the efficiency of heat transmission of the crystal growing device during the crystal growing process. The heat exchanging unit 63 includes an outer tubular body 631 in contact with the heat transmitting block 5, and an inner tubular body 632 disposed in the outer tubular body 631 and establishing fluid communication with the outer tubular body 631 and the flow controlling unit 62. The outer tubular body 631 is partially inserted into the heat transmitting block 5 and defines a third channel 601 along the axis (L) therein and in spatial communication with the second channel 501. The fluid supplied by the fluid supplying unit 61 flows through the flow controlling unit 62, the inner tubular body 632 of the heat exchanging unit 63, and the outer tubular body 631 of the heat exchanging unit 63, and flows out of the heat exchanging unit 63. When the fluid flows through the outer tubular body 631, Heat exchange effect occurs and heat absorbed from the heat transmitting block 5 will be taken away via the fluid flowing out of the heat exchanging unit 63. Such fluid may be recycled, cooled and ready for use again.

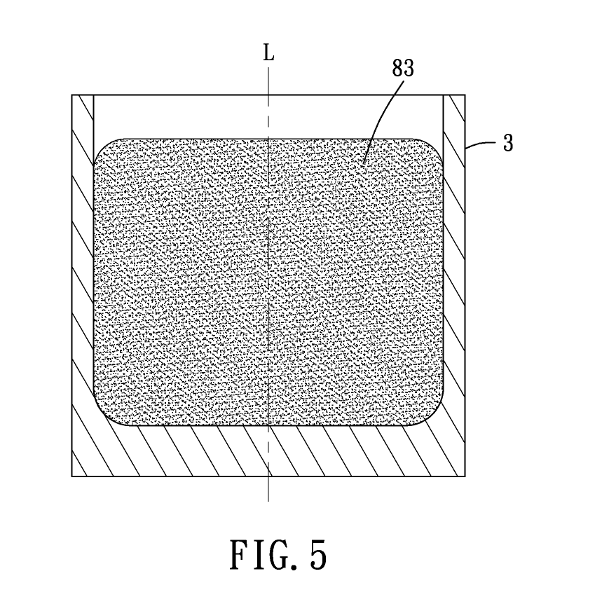

Although the heat exchanging unit 63 is only able to absorb heat from a portion of the heat transmitting block 5 proximate to the axis (L), the top surface 51 of the heat transmitting block 5 still has uniform heat distribution due to the high thermal conductivity per se during the crystal growing process. Moreover, when an insertion depth D1 of the outer tubular body 631 ranges from 25% to 45% of a thickness D2 of the heat transmitting block 5, the top surface 51 of the heat transmitting block 5 has a more uniform distribution of heat during the crystal growing process. Therefore, heat of the raw material 81 is capable of being transmitted evenly and downwardly through the crystal seed layer 82, the crucible 3, the platform 2, and the heat transmitting block 5 to the heat exchanging unit 63 of heat exchanger 6. Such uniform transmission prevents the crystal seed layer 82 from being melted, and a crystal 83 with an even top surface is attained when the crystal growing process is finished (see FIG. 5).

The temperature sensor 7 is configured in a rod shape, is disposed in the first channel 201, the second channel 501, and the third channel 601 along the axis (L), and extends downwardly and outwardly through the furnace 11. The temperature sensor 7 has a top end close to the bottom wall 31 of the crucible 3 so as to be able to measure the temperature of crucible 3 proximate to the axis (L). The temperature sensor 7 is connected to a control circuit (not shown) which is able to control the heating unit 4 to alter the temperature of the raw material 81 based on the measurement of the temperature sensor 7 for achieving a better yield of the crystal growing process.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. A crystal growing device comprising:
a furnace defining a chamber therein;
a platform disposed in said chamber and having a top surface and a bottom surface;
a crucible disposed on said top surface of said platform for receiving a crystal seed layer and a raw material therein;
a heating unit disposed in said chamber and surrounding said crucible;
a heat transmitting block disposed at said bottom surface of said platform and made of a material with high thermal conductivity; and
a heat exchanger coupled to said heat transmitting block for absorbing heat from said heat transmitting block.

2. The crystal growing device as claimed in claim 1, wherein said heat transmitting block has a top surface in direct contact with said bottom surface of said platform.

3. The crystal growing device as claimed in claim 2, wherein said heat transmitting block further has a bottom surface, an upper side surface connected to said top surface of said heat transmitting block, and a lower side surface connected to said upper side surface and said bottom surface of said heat transmitting block and tapering downwardly from said upper side surface.

4. The crystal growing device as claimed in claim 3, wherein an angle formed between said lower side surface and said bottom surface of said heat transmitting block ranges from 145° to 165°.

5. The crystal growing device as claimed in claim 2, wherein a surface area of said top surface of said heat transmitting block is not less than 70% of a surface area of said bottom surface of said platform.

6. The crystal growing device as claimed in claim 1, wherein the material from which said heat transmitting block is made is selected from graphite, molybdenum, and tungsten.

7. The crystal growing device as claimed in claim 1, wherein said heat exchanger includes a fluid supplying unit for supplying a fluid, a flow controlling unit connected to said fluid supplying unit for controlling a flow rate of the fluid, and a heat exchanging unit connected to said flow controlling unit and in contact with said heat transmitting block.

8. The crystal growing device as claimed in claim 7, wherein:
said platform defines a first channel therein, said heat transmitting block defines a second channel therein that is in spatial communication with said first channel, and said heat exchanging unit defines a third channel therein that is in spatial communication with said second channel;
said first channel, said second channel, and said third channel extend along an axis of said crucible;
said crucible has a bottom surface; and
said crystal growing device further comprises a temperature sensor that is disposed in said first channel, said second channel and said third channel, and that has one end proximate to said bottom surface of said crucible.

9. The crystal growing device as claimed in claim 8, wherein said heat exchanging unit includes an outer tubular body in contact with said heat transmitting block, and an inner tubular body disposed in said outer tubular body and establishing fluid communication between said flow controlling unit and said outer tubular body, said outer tubular body defining said third channel therein.

10. The crystal growing device as claimed in claim 9, wherein said heat transmitting block has a thickness, and said outer tubular body is partially inserted into said heat transmitting block from said bottom surface of said heat transmitting block to an insertion depth that ranges from 25% to 45% of the thickness of said heat transmitting block.

11. The crystal growing device as claimed in claim 7, wherein the fluid supplied by said fluid supplying unit has high thermal conductivity.

12. The crystal growing device as claimed in claim 11, wherein the fluid supplied by said fluid supplying unit is an inert gas.
